(19) United States
(12) Patent Application Publication
(10) Pub. No.: US 2011/0315434 A1
(43) Pub. Date: Dec. 29, 2011

(54) FINE ALUMINUM HYDROXIDE POWDER FOR FILLING IN RESIN AND METHOD FOR PRODUCING THE SAME

(75) Inventor: Yusuke Kawamura, Niihama-shi (JP)

(73) Assignee: SUMITOMO CHEMICAL COMPANY, LIMITED, Chuo-ku, Tokyo (JP)

(21) Appl. No.: 13/201,108

(22) PCT Filed: Feb. 12, 2010
(86) PCT No.: PCT/JP2010/052487

§ 371 Date: Aug. 11, 2011

(30) Foreign Application Priority Data
Feb. 13, 2009 (JP) 2009-030854

(51) Int. Cl. H05K 1/03; C08L 63/00; B32B 5/16; C08L 21/00; C08L 23/12; C01F 7/14; C08K 3/22

(52) U.S. Cl. 174/256; 423/629; 523/440; 524/437; 428/402

(57) ABSTRACT

The object of the present invention is to provide an aluminum hydroxide powder for filling in resin, which is excellent fillability in resin. Provided is an aluminum hydroxide powder forfilling in resin, being characterized in that it comprises a gibbsite crystal structure.

### TECHNICAL FIELD

The present invention relates to a fine aluminum hydroxide powder for filling in resin, and a method for producing the same.

### BACKGROUND ART

With recent miniaturization of an electronic equipment, not only further miniaturization but also safety is required to components such as electronic components of the electronic equipment. From the viewpoint of safety, high flame retardancy is required to components. International Publication No. WO 2008-090614 discloses use of an aluminum hydroxide powder as a flame retardant, which is mixed in various resin materials used in a printed circuit board, electronic components constituting the printed circuit board, such as a prepreg, an electric wire coating material, an insulating material and the like thereby imparting flame retardancy to the resin materials. Practically, an aluminum hydroxide powder having a mean particle diameter of not more than 5 μm is used. However, when such an aluminum hydroxide powder having a small mean particle diameter is filled in a resin and mixed, viscosity of the obtained resin composition increases and thus workability may become worse. Therefore, depending on the resin, a sufficient amount of the aluminum hydroxide powder cannot be mixed and thus flame retardancy sometimes may not be imparted.

JP-A-2-199020 discloses, as an aluminum hydroxide powder for filling in resin, which is excellent in fillability in the case of filling in the resin, an aluminum hydroxide ground by applying a centrifugal force of not less than 1,000 G to a slurry containing the aluminum hydroxide using a continuous centrifugal separator. Such an aluminum hydroxide has a mean particle diameter of 2 to 8 μm and small oil absorption of linseed oil, and a resin composition obtained by mixing into the resin has small viscosity.

JP-A-2001-322813 discloses a method of producing an aluminum hydroxide powder having small dioctyl phthalate (DOP) oil absorption and excellent fillability in a resin by grinding a raw aluminum hydroxide powder using a screw-type kneader.

### DISCLOSURE OF THE INVENTION

The present inventors have intensively studied so as to develop a fine aluminum hydroxide powder for filling in resin, which is excellent fillability in resin, thus leading to the present invention.

The present invention includes the following constitutions.

(1) A fine aluminum hydroxide powder for filling in resin, comprising a gibbsite crystal structure, wherein a mean particle diameter is not less than 2.0 μm nor more than 4.0 μm in particle size distribution measured by a laser scattering diffraction method; a ratio D90/D10 of a secondary particle diameter D10 corresponding to a point where a cumulative weight from a fine particle portion reaches 10%, to a secondary particle diameter D90 corresponding to a point where a cumulative weight from a fine particle portion reaches 90% is not less than 4.0 nor more than 6.0; two or more frequency maximums exists in a particle diameter range I of not less than 0.5 μm nor more than 5.0 μm; D2 and D1 satisfy the inequality expression (1):

2×D1≦D2≦4×D1 (1)

where D2 denotes a maximum particle diameter of a frequency maximum having a largest maximum particle diameter, among two or more frequency maximums existing in a particle diameter range I, and D1 denotes a maximum particle diameter of a frequency maximum having the smallest maximum particle diameter; an intensity ratio I (110)/I (002) between peaks at crystal planes (110) and (002) measured by powder X-ray diffraction is not less than 0.30 nor more than 0.45; and the total sodium content is not more than 0.10% by weight in terms of Na₂O.
(2) The fine aluminum hydroxide powder for filling in resin according to the above (1), being subjected to a surface treatment with at least one selected from a group consisting of; a silane coupling agent, a titanate coupling agent, an aliphatic carboxylic acid, an aromatic carboxylic acid, a fatty acid ester, and a silicate compound. (3) A method for producing fine aluminum hydroxide powder for filling in resin, comprising the steps (a) and (b):

step (a) of adding an aqueous supersaturated sodium aluminate solution to an aqueous sodium aluminate slurry containing seed aluminum hydroxide in which a BET specific surface area is not less than 2.0 m²/g nor more than 5.0 m²/g, a mean particle diameter measured by a laser scattering diffraction method in particle size distribution is not less than 1.0 μm and less than 3.0 μm, the total sodium content is not more than 0.20% by weight in terms of Na₂O, and an intensity ratio I (110)/I (002) between peaks at crystal planes (110) and (002) is more than 0.45, thereby precipitating a coarse aluminum hydroxide in which an intensity ratio I (110)/I (002) between peaks at crystal planes (110) and (002) measured by powder X-ray diffraction is more than 0.45; and

step (b) of allowing a fine aluminum hydroxide powder for filling in resin obtained by grinding the coarse aluminum hydroxide being characterized in that a ratio D90/D10 of a secondary particle diameter D10 corresponding to a point where a cumulative weight from the fine particle portion reaches 10%, to a secondary particle diameter D90 corresponding to a point where a cumulative weight from the fine particle portion reaches 90% is not less than 4.0 nor more than 6.0, and an intensity ratio I (110)/I (002) between peaks at crystal planes (110) and (002) measured by powder X-ray diffraction is not less than 0.30 nor more than 0.45 in particle size distribution measured by a laser scattering diffraction method.

(4) The method according to the above (3), wherein a ratio of D90/D10 of a secondary particle diameter D10 corresponding to the point where the cumulative weight from the fine particle portion reaches 10%, to a secondary particle diameter D90 corresponding to the point where the cumulative weight from the fine particle portion reaches 90% of the seed aluminum hydroxide is not less than 2.0 nor more than 5.0 in particle size distribution measured by a laser scattering diffraction method.
(5) A resin composition comprising: a resin; and the fine aluminum hydroxide powder for filling in resin according to the above (1) or (2).
(6) A prepreg comprising the resin composition according to the above (5).
(7) A printed circuit board including the resin composition according to the above (5).

### BEST MODE FOR CARRYING OUT THE INVENTION

Embodiments of the present invention will be described in detail below.

### (Fine Aluminum Hydroxide Powder for Filling in Resin)

The fine aluminum hydroxide powder for filling in resin of the present invention (hereinafter also referred to as an aluminum hydroxide powder of the present invention) has a gibbsite crystal structure, wherein a mean particle diameter is not less than 2.0 μm nor more than 4.0 μm; a ratio D90/D10 of a secondary particle diameter D10 corresponding to the point where the cumulative weight from the fine particle portion reaches 10%, to a secondary particle diameter D90 corresponding to the point where the cumulative weight from the fine particle portion reaches 90% is not less than 4.0 nor more than 6.0 in particle size distribution measured by a laser scattering diffraction method; D2 and D1 satisfy the inequality expression (1):

2×D1≦D2≦4×D1 (1)

where D2 denotes a maximum particle diameter of a frequency maximum having the largest maximum particle diameter, among two or more frequency maximums existing in a particle diameter range I of not less than 0.5 μm nor more than 5.0 μm, and D1 denotes a maximum particle diameter of a frequency maximum having the smallest maximum particle diameter; an intensity ratio I (110)/I (002) between peaks at crystal planes (110) and (002) measured by powder X-ray diffraction is not less than 0.30 nor more than 0.45; and the total sodium content is not more than 0.10% by weight in terms of Na₂O.

The aluminum hydroxide powder of the present invention is a powder of a gibbsite type aluminum hydroxide, that is, aluminum hydroxide [Al(OH)₃] comprising as a main crystal phase a gibbsite phase. The gibbsite type aluminum hydroxide may slightly contain a boehmite phase, a bayerite phase and the like. When the gibbsite type aluminum hydroxide contains the boehmite phase and the bayerite phase, a peak height of a main peak at the boehmite phase and that of the bayerite phase in a powder X-ray diffraction spectrum are preferably not more than 5% of a peak height of a main peak at the gibbsite phase, respectively. The gibbsite type aluminum hydroxide may also contain an amorphous aluminum hydroxide.

The mean particle diameter, the cumulative weight from the fine particle portion, and the maximum particle diameter of the aluminum hydroxide powder of the present invention are calculated from a particle diameter and a particle size distribution curve measured by a laser scattering diffraction method.

In that case, the particle size distribution measured by a laser scattering diffraction method of the aluminum hydroxide powder of the present invention expresses frequency distribution to common logarithm of a particle diameter [log(particle diameter)] on a weight basis, and a step value (class in histogram) of [log(particle diameter)] means particle size distribution measured at 0.038 in the present description.

The mean particle diameter of the aluminum hydroxide powder of the present invention is not less than 2.0 μm nor more than 4.0 μm, and preferably not less than 2.5 μm nor more than 3.5 μm. When the mean particle diameter of the aluminum hydroxide powder is less than 2.0 μm, deterioration of fillability cannot be avoided. In contrast, when the mean particle diameter is more than 4.0 μm, coarse particles having a diameter of not less than 10 μm cannot be avoided and thus it is difficult to impart insulating properties to the miniaturized and thinned electronic material.

The aluminum hydroxide powder of the present invention has sharp particle size distribution. Specifically, a ratio of D10 to D90 (D90/D10) is not less than 4.0 nor more than 6.0 when D10 denotes a particle diameter corresponding to the point where the cumulative weight from the fine particle portion reaches 10%, and D90 denotes a particle diameter corresponding to the point where the cumulative weight from the fine particle portion reaches 90% in particle size distribution measured by a laser scattering diffraction method.

When D90/D10 is more than 6.0, there arises a large difference between a particle diameter of the fine particle portion and a particle diameter of the coarse particle portion in particle size distribution. When such an aluminum hydroxide powder is mixed in a resin, compound physical properties of the obtained resin composition vary widely. When D90/D10 is less than 4.0, it is impossible to have two or more frequency maximums in particle size distribution.

Particle size distribution of secondary particles formed by aggregation of primary particles is measured by a laser scattering diffraction method. In the measurement of laser scattering type particle size distribution, “Microtrac HRA” manufactured by Nikkiso Co., Ltd. and “Microtrac MT-3300EX” which is a succeeding model thereof can be used. In the case of using “Microtrac MT-3300EX”, mode used upon calculation of particle size distribution is measured as “HRA mode”.

The aluminum hydroxide powder of the present invention has two or more frequency maximums. The number of frequency maximums is preferably 2 or 3, and more preferably 2. The maximum particle diameter of the frequency maximum in particle size distribution of an aluminum hydroxide powder, the number of the frequency maximum, and the frequency in the maximum particle diameter can be examined from particle size distribution obtained by measuring of a slurry obtained by dispersing an aluminum hydroxide powder in water using a laser scattering diffraction method.

Herein, “frequency maximum in particle size distribution” means a frequency maximum in which a ratio M4/M3 of a minimum frequency M3 of any particle diameter, to a frequency M4 of a frequency maximum having a small frequency among adjacent two frequency maximums in a particle diameter range between adjacent two frequency maximums is not less than 1.01.

The aluminum hydroxide powder of the present invention has two or more frequency maximums in a particle diameter range I of not less than 0.5 μm nor more than 5.0 μm and, when D2 denotes a maximum particle diameter of a frequency maximum having the largest maximum particle diameter among frequency maximums in the particle diameter range I, and D1 denotes a maximum particle diameter of a frequency maximum having the smallest maximum particle diameter, a ratio (M1/M2) of M2 to M1, which are frequencies at each particle diameter of the maximum particle diameters D1 and D2, is preferably not less than 0.10 nor more than 0.70, more preferably not less than 0.20 nor more than 0.60, and still more preferably not less than 0.40 nor more than 0.60. In case that (M1/M2) is less than 0.10, when an aluminum hydroxide powder is mixed in a resin, the obtained resin composition exhibits behavior close to that of a resin composition containing only particles having a maximum particle diameter D2 mixed therein, and thus fillability becomes worse. In case that (M1/M2) is more than 0.70, since a space between particles increases by an increase in the content of fine particles in the aluminum hydroxide powder, fillability becomes worse.

In the aluminum hydroxide powder of the present invention, D2 and D1 satisfy the following inequality expression (1).

2×D1≦D2≦4×D1 (1)

When D2 is less than 2×D1, since there is a small difference between the largest maximum particle diameter and the smallest maximum particle diameter, fillability of the aluminum hydroxide powder in a resin becomes worse. When D2 is more than 4×D1, since the particle diameter D2 is relatively more than the particle diameter D1, the content of particles having a particle diameter more than the mean particle diameter is high. For example, even if the mean particle diameter of the aluminum hydroxide powder is no more than 4 μm, actually, most of particles are particles having particle diameter of more than 4 μm and it is difficult to use in applications where miniaturization and thinning are required, such as a printed circuit board. Specifically, it is preferred that particles having the particle diameter D1 exist in a particle diameter range of not less than 1.0 μm nor more than 2.0 μm, and particles having the particle diameter D2 exist in a particle diameter range of not less than 3 μm nor more than 5 μm.

In the aluminum hydroxide powder of the present invention, an intensity ratio I (110)/I (002) of an intensity I (110) of a peak at the crystal plane (110) to an intensity I (002) of a peak at the crystal plane (002) measured by powder X-ray diffraction is not less than 0.30 nor more than 0.45. An aluminum hydroxide powder having a peak intensity ratio I (110)/I (002) of less than 0.30 means that a (002) plane is large and the powder shape is tabular, and an aluminum hydroxide powder having a peak intensity ratio I (110)/I (002) of more than 0.45 means that a (002) plane is small and the powder shape is distorted or columnar, and such an aluminum hydroxide powder exhibits low fillability in a resin.

In the aluminum hydroxide powder of the present invention, the total sodium content in terms of Na₂O (hereinafter also referred to as a Na₂O content) is not more than 0.10% by weight, and preferably not more than 0.05% by weight. The total sodium content in terms of Na₂O can be measured by the method in accordance with JIS-R9301-3-9.

In a resin composition containing an aluminum hydroxide powder having a Na₂O content of more than 0.10% by weight mixed therein, thermal decomposition property and insulating properties in a resin become worse, and thus it becomes difficult to use in applications where heat resistance is required, such as electronic components.

Since the soluble sodium component which can be removed by washing drastically exerts an influence on insulating properties, the content is preferably not more than 0.002% by weight.

In the aluminum hydroxide powder of the present invention, the BET specific surface area is preferably not more than 5.0 m²/g, and more preferably not less than 2.0 m²/g nor more than 4.0 m²/g. When the BET specific surface area is more than 5.0 m²/g, the content of fine particles such as chipping particles relatively increases and thus heat resistance and fillability in a resin of a resin composition containing an aluminum hydroxide powder mixed therein become worse.

It is preferred that the aluminum hydroxide powder of the present invention is subjected to a surface treatment with surface treating agents, for example, a silane coupling agent, a titanate coupling agent, an aliphatic carboxylic acid such as oleic acid or stearic acid, an aromatic carboxylic acid such as benzoic acid, and a fatty acid ester thereof, a silicate compound such as methyl silicate or ethyl silicate, and the like for the purpose of improving affinity with a resin, and fillability. The surface treatment can be performed by any of dry and wet treatment methods.

Specific examples of the dry surface treatment method include a method in which an aluminum hydroxide powder is mixed with a surface treating agent in a Henschel mixer or a Loedige mixer, a method in which a mixture of an aluminum hydroxide powder and a surface treating agent is fed in a grinder and ground so as to coat with the surface treating agent more uniformly, and the like.

Examples of the wet surface treatment method include a method in which a surface treating agent is dispersed or dissolved in a solvent and an aluminum hydroxide powder is dispersed in the obtained solution, and then the obtained aluminum hydroxide dispersion is dried, and the like.

### (Method for Producing Fine Aluminum Hydroxide Powder for Filling in Resin)

The method for producing a fine aluminum hydroxide powder for filling in resin of the present invention (hereinafter also referred to as a method of the present invention) includes the steps (a) and (b): step (a) of adding an aqueous supersaturated sodium aluminate solution to an aqueous sodium aluminate slurry containing seed aluminum hydroxide in which a BET specific surface area is not less than 2.0 m²/g nor more than 5.0 m²/g, a mean particle diameter measured by a laser scattering diffraction method in particle size distribution is not less than 1.0 μm and less than 3.0 μm, the total sodium content is not more than 0.20% by weight in terms of Na₂O, and an intensity ratio I (110)/I (002) between peaks at crystal planes (110) and (002) is more than 0.45, thereby precipitating a coarse aluminum hydroxide in which an intensity ratio I (110)/I (002) between peaks at crystal planes (110) and (002) measured by powder X-ray diffraction is more than 0.45; and

step (b) of allowing a fine aluminum hydroxide powder for filling in resin obtained by grinding the coarse aluminum hydroxide being characterized in that a ratio D90/D10 of a secondary particle diameter D10 corresponding to the point where the cumulative weight from the fine particle portion reaches 10%, to a secondary particle diameter D90 corresponding to the point where the cumulative weight from the fine particle portion reaches 90% is not less than 4.0 nor more than 6.0 in particle size distribution measured by a laser scattering diffraction method, and an intensity ratio I (110)/I (002) between peaks at crystal planes (110) and (002) measured by powder X-ray diffraction is not less than 0.30 nor more than 0.45.

Specific examples of the method of the present invention include a method in which a coarse aluminum hydroxide is obtained by a so-called Bayer process of adding the below-mentioned seed aluminum hydroxide in an aqueous supersaturated sodium aluminate solution or adding an aqueous supersaturated sodium aluminate solution to an aqueous sodium aluminate slurry containing seed aluminum hydroxide, thereby precipitating aluminum hydroxide in the aqueous solution on a surface of the seed aluminum hydroxide, and allowing the seed aluminum hydroxide to undergo grain growth, and then the obtained coarse aluminum hydroxide is ground, and the like.

In the seed aluminum hydroxide used in the method of the present invention, a BET specific surface area is not less than 2.0 m²/g nor more than 5.0 m²/g, and preferably not more than 4.0 m²/g. In case that the BET specific surface area is more than 5.0 m²/g, when aluminum hydroxide is precipitated in an aqueous supersaturated sodium aluminate solution, incorporation of a sodium component in the aqueous solution into aluminum hydroxide to be precipitated becomes easy.

In the seed aluminum hydroxide used in the method of the present invention, a mean particle diameter measured by a laser scattering diffraction method is not less than 1.0 μm nor more than 3.0 μm. When a seed aluminum hydroxide having a mean particle diameter of more than 3.0 μm is used, it is impossible to obtain an aluminum hydroxide powder which contains Na₂O in the concentration of not more than 0.10% by weight and is also excellent in fillability in a resin. When the mean particle diameter is less than 1.0 μm, seed aluminum hydroxides are likely to aggregate with each other at the initial stage of precipitating an aluminum component contained in the aqueous solution on a surface of the seed aluminum hydroxide and coarse aluminum hydroxide is precipitated while incorporating the aqueous sodium aluminate solution into a gap due to aggregation, and thus the concentration of sodium in the aluminum hydroxide powder obtained by grinding the coarse aluminum hydroxide increases.

In the seed aluminum hydroxide used in the method of the present invention, a ratio D90/D10 of a secondary particle diameter D10 corresponding to the point where the cumulative weight from the fine particle portion reaches 10%, to a secondary particle diameter D90 corresponding to the point where the cumulative weight from the fine particle portion reaches 90% is preferably not less than 2.0 nor more than 5.0, and more preferably not less than 3.0 nor more than 4.5 in particle size distribution measured by a laser scattering diffraction method. When D90/D10 is more than 5.0, since the proportion of coarse particles to particles having the mean particle diameter is large, the coarse aluminum hydroxide obtained by the subsequent precipitation has wide particle size distribution and thus it is sometimes impossible to obtain the aluminum hydroxide powder of the present invention. In contrast, when D90/D10 is less than 2.0, since particle size distribution is very narrow, the coarse aluminum hydroxide obtained by the subsequent precipitation has narrow particle size distribution. The aluminum hydroxide powder obtained by grinding such a coarse aluminum hydroxide having narrow particle size distribution sometimes have not two or more frequency maximums.

In the seed aluminum hydroxide used in the method of the present invention, the aggregation degree represented by a ratio D/Dbet of Dbet calculated from BET specific surface area S by spherical approximation to a mean secondary particle diameter D is preferably not more than 5, and more preferably not more than 4.

Dbet is calculated by the following equation (x).

Dbet=6/(BET specific surface area×true density) (x)

The Na₂O content of the seed aluminum hydroxide used in the method of the present invention is not more than 0.20% by weight, and preferably not more than 0.15% by weight, based on the total weight of the seed aluminum hydroxide. When the Na₂O content is more than 0.20% by weight, Na₂O content distribution arises in the obtained aluminum hydroxide powder and thermal decomposition is locally started at a low temperature in the resin composition containing the aluminum hydroxide powder. Therefore, it becomes difficult to use the obtained resin composition in applications where heat resistance is required.

In the seed aluminum hydroxide used in the method of the present invention, the intensity ratio I (110)/I (002) between peaks at crystal planes (110) and (002) measured by powder X-ray diffraction is more than 0.45 and not more than 0.60. By precipitating an aluminum component on a surface of the seed aluminum hydroxide, a coarse aluminum hydroxide having a peak ratio of more than 0.45 and not more than 0.60 is obtained.

Examples of the method for producing a seed aluminum hydroxide used in the method of the present invention include a method in which an ultrafine aluminum hydroxide having a primary particle diameter of less than 1.0 μm is added in an aqueous supersaturated sodium aluminate solution to precipitate a seed aluminum hydroxide.

The ultrafine aluminum hydroxide having a primary particle diameter of less than 1.0 μm is obtained, for example, as a neutralized gel by mixing an aqueous supersaturated sodium aluminate solution and an aqueous acidic solution with stirring.

It is possible to use, as an aqueous acidic solution, hydrochloric acid, sulfuric acid, nitric acid, an aqueous aluminum chloride solution, an aqueous aluminum sulfate solution and the like, preferably an aqueous aluminum-containing acidic solution such as an aqueous aluminum chloride solution or an aqueous aluminum sulfate solution, and more preferably an aqueous aluminum sulfate solution.

In this case, a crystal structure of a solid matter in the neutralized gel preferably includes both gibbsite and bayerite. Specifically, it is preferred that an intensity ratio I (001)/I (002) between peaks at the crystal plane (002) of gibbsite and the crystal plane (001) of bayerite measured by powder X-ray diffraction is not less than 0.40 nor more than 0.80. When the intensity ratio is less than 0.40 or the crystal structure includes only gibbsite, ultrafine aluminum hydroxides may sometimes aggregate, and thus it is sometimes impossible to obtain an ultrafine aluminum hydroxide having a primary particle diameter of less than 1.0 μm.

It is also preferred that the BET specific surface area of the ultrafine aluminum hydroxide contained in the neutralized gel is not less than 20 m²/g nor more than 100 m²/g.

In order to precipitate the seed aluminum hydroxide used in the method of the present invention, when the ultrafine aluminum hydroxide having a primary particle diameter of less than 1.0 μm is added in the aqueous supersaturated sodium aluminate solution, the amount of aluminum in terms of Al₂O₃ in the neutralized gel containing the ultrafine aluminum hydroxide is preferably not less than 0.5% by weight nor more than 3.0% by weight based on the amount of aluminum in terms of Al₂O₃ in the aqueous supersaturated sodium aluminate solution. When the amount of aluminum is less than 0.5% by weight, the ultrafine aluminum hydroxide grows at a high rate and thus the seed aluminum hydroxide, into which a large amount of a sodium component in the aqueous solution has been incorporated during the growing process, may be sometimes precipitated. When the amount of aluminum is more than 3.0% by weight, the ultrafine aluminum hydroxide does not sufficiently grow and thus it is sometimes impossible to obtain a seed aluminum hydroxide having a mean particle diameter of not less than 1.0 μm.

Herein, the amount of aluminum in the aqueous supersaturated sodium aluminate solution or the neutralized gel containing the ultrafine aluminum hydroxide can be measured by a chelatometric titration method.

The amount of aluminum in terms of Al₂O₃ in the aqueous supersaturated sodium aluminate solution or the neutralized gel containing the ultrafine aluminum hydroxide can be obtained from the measured amount of aluminum by the following equation (y).

X=Y×102/2 (y)

In the equation (y), X represents the concentration (g/L) of Al₂O₃, Y represents the amount of aluminum (mol/L) measured by a chelatometric titration method, and 102 represents the molecular weight of Al₂O₃.

When the neutralized gel containing the ultrafine aluminum hydroxide is obtained by mixing the aqueous supersaturated sodium aluminate solution and the aqueous acidic solution, the amount of aluminum in the neutralized gel is the total amount of the amount of aluminum in the aqueous supersaturated sodium aluminate solution and the amount of aluminum in the aqueous acidic solution.

With respect to the concentration condition of the aqueous supersaturated sodium aluminate solution to which the ultrafine aluminum hydroxide is added, the concentration of supersaturated Al₂O₃ is preferably not more than 75 g/L before the addition of the ultrafine aluminum hydroxide. The concentration (X) of supersaturated Al₂O₃ is calculated by the following equation (2) described in International Publication No. WO 2008-090614.

X=A×C×exp[6.2106−{(2486.7−1.0876×C)/(T+273)}] (2)

In the above equation (2), A represents the concentration (g/L) of Al₂O₃ in the aqueous sodium aluminate solution, and C represents the concentration (g/L) of Na₂O, that is, they represent the concentrations of Al and Na in terms of Al₂O₃ and Na₂O on a weight basis. T represents a solution temperature (° C.).

In the aqueous sodium aluminate solution and the aqueous supersaturated sodium aluminate solution in the method of the present invention, the concentration of Al₂O₃ is preferably not less than 40 g/L nor more than 200 g/L, and the concentration of Na₂O is preferably not less than 100 g/L nor more than 250 g/L.

The time required to precipitate the seed aluminum hydroxide used in the method of the present invention is preferably not less than 2 hours nor more than 200 hours, and more preferably not less than 20 hours nor more than 150 hours, after the addition of the ultrafine aluminum hydroxide in the aqueous supersaturated sodium aluminate solution.

By adding the aqueous supersaturated sodium aluminate solution in the obtained aqueous sodium aluminate slurry containing the seed aluminum hydroxide, precipitation of aluminum hydroxide on a surface of the seed aluminum hydroxide is started and the particle diameter gradually increased, and thus a coarse aluminum hydroxide is obtained.

With respect to the concentration condition of the aqueous sodium aluminate slurry containing the seed aluminum hydroxide, since precipitation of the seed aluminum hydroxide has been completed, the concentration of supersaturated Al₂O₃ is preferably within the below-mentioned saturated concentration ±15 g/L. When the concentration of Al₂O₃ in the aqueous sodium aluminate slurry is more than the saturated concentration +15 g/L, the concentration of supersaturated Al₂O₃ during the addition of the aqueous supersaturated sodium aluminate solution becomes higher and a rate of precipitation of aluminum hydroxide on a surface of the seed aluminum hydroxide increases, and thus the concentration of Na₂O in the coarse aluminum hydroxide may sometimes becomes higher.

The above saturated concentration can be calculated by the following equation (3).

a=C×exp[6.2106−{(2486.7−1.0876×C)/(T+273)}] (3)

“a” represents the concentration (g/L) of saturated Al₂O₃. C represents concentration of Na₂O in the aqueous sodium aluminate solution, that is, the concentration of Na in terms of Na₂O on a weight basis. T represents a solution temperature (° C.).

It is preferred that the amount of the seed aluminum hydroxide contained in the aqueous sodium aluminate slurry and the amount of the aqueous supersaturated sodium aluminate solution to be added to the aqueous sodium aluminate slurry are adjusted so that a mean particle diameter of the obtained coarse aluminum hydroxide becomes not less than 4.0 μm nor more than 8.0 μm, and preferably not less than 5.0 μm nor more than 7.0 μm. Commonly, when the additive amount of the aqueous supersaturated sodium aluminate solution becomes excessive to the amount of the seed aluminum hydroxide, the mean particle diameter of the obtained coarse aluminum hydroxide is sometimes more than 8.0 μm. When the amount of the aqueous supersaturated sodium aluminate solution is small, the mean particle diameter of the obtained coarse aluminum hydroxide is sometimes less than 4.0 μm. When the mean particle diameter of the coarse aluminum hydroxide is more than 8 μm, it is impossible to obtain a fine aluminum hydroxide powder for filling in resin having the above particle size distribution.

The coarse aluminum hydroxide in the method of the present invention may be washed. For example, the coarse aluminum hydroxide may be filtered by a filter press or the like, subjected to solid-liquid separation by centrifugal separation using a screw decanter or the like, and washed with water. Water used in washing is preferably hot water at 60 to 90° C. since a soluble sodium component adhered on a surface of the coarse aluminum hydroxide can be efficiently removed.

The coarse aluminum hydroxide in the method of the present invention usually aggregates and has a large particle diameter. By grinding the coarse aluminum hydroxide, a fine aluminum hydroxide powder for filling in resin having the above-mentioned particle size distribution can be obtained.

The coarse aluminum hydroxide can be ground by a known method, and examples of the method include a method of grinding using a medium such as a vibrating mill or a ball mill, a method of grinding by a given centrifugal force or more using a continuous centrifugal separator such as a screw decanter, and a method of grinding using a kneader and the like. However, the grinding method using the medium applies a very strong grinding strength, and D90/D10 of the obtained aluminum hydroxide powder is sometimes more than 6.0. Therefore, the method of grinding using the medium is not preferred, and the method of grinding using the continuous centrifugal separator and the method of grinding using the kneader are preferred. Whereby, a fine aluminum hydroxide powder for filling in resin, which is excellent in fillability in the resin, can be obtained.

When the obtained fine aluminum hydroxide powder for filling in resin contains not less than 1% by weight of water, it is preferred to dry the powder at a temperature of not lower than 100° C. Drying can be performed by a known method.

### (Resin Composition, Component and the Like)

The aluminum hydroxide powder of the present invention has a low Na₂O content and less anisotropy, and also two or more frequency maximums in particle size distribution in spite of a small mean particle diameter and sharp particle size distribution, and is therefore suited for use as a filler in various resins.

Examples of the resin include thermoplastic resins such as rubber and polypropylene; and thermosetting resins such as an epoxy resin; and the like.

Examples of specific applications of the resin composition obtained by mixing the aluminum hydroxide powder of the present invention in various resins include, in addition to components such as a printed circuit board, electronic components of an electronic equipment, which constitute the printed circuit board, such as a prepreg, an electric wire coating material, a polyolefin molding material, a tire, a building material such as an artificial marble, and the like.

The present invention will be described in more detail below by way of Examples and Comparative Examples, but the present invention is not limited to these descriptions.

The respective physical properties of the fine aluminum hydroxide powder for filling in resin in Examples and Comparative Examples were measured by the following procedures.

### (1) Measurement of Mean Particle Diameter, Maximum Particle Diameter and Maximum Frequency

Using a laser scattering particle size distribution analyzer [“Microtrac HRA X-100”, manufactured by Nikkiso Co., Ltd.], a powder was added in an aqueous 0.2% by weight sodium hexametaphosphate solution. After adjustment to a measurable concentration and further irradiation with ultrasonic wave at an output of 40 W for 5 minutes, the measurement was made two times and a particle diameter and a particle size distribution curve were determined from a mean value thereof. The mean particle diameter was determined as a particle diameter equivalent to 50% by weight particle diameter (D50 (μm)). The secondary particle diameter D10 corresponding to the point where the cumulative weight from the fine particle portion reaches 10%, and the secondary particle diameter D90 corresponding to the point where the cumulative weight from the fine particle portion reaches 90% were also calculated from this particle size distribution. The maximum particle diameter was determined from a particle diameter which exhibits a frequency maximum in particle size distribution. Frequencies M1, M2 (%), and maximum particle diameters D1, D2 (μm) at a frequency maximum were determined from the value obtained when a step width of [log(particle diameter)] is 0.038.

### (2) Measurement of Powder X-ray Diffraction and Intensity Ratio I (110)/I (002) of Peak

Using a powder X-ray diffraction meter [“RINT-2000”, manufactured by Rigaku Corporation] and using Cu as an X-ray source, the measurement was made under the following measuring conditions.

Step width: 0.02 deg

Scan speed: 0.04 deg/sec

Acceleration voltage: 40 kV

Acceleration current: 30 mA

The results measured under the above measuring conditions were compared with JCPDS card 70-2038 (corresponding to gibbsite), and a peak intensity ratio I (110)/I (002) was determined from each peak height corresponding to (110) plane and (002) plane. Also, JCPDS card 70-2038 was compared with JCPDS card 74-1119 (corresponding to bayerite), and each peak intensity ratio I (001)/I (002) was determined from each peak corresponding to (001) plane of bayerite and (002) plane of gibbsite.

### (3) BET Specific Surface Area

In accordance with the method defined in JIS-Z-8830, a BET specific surface area was determined by a nitrogen adsorption method.

(4) Dioctyl Phthalate Oil Absorption (ml/100 g; Hereinafter Referred to as DOP Oil Absorption)

In accordance with the method defined in JIS-K-6221, DOP oil absorption was determined. As DOP oil absorption of a fine aluminum hydroxide powder for filling in resin becomes lower, fillability in resin is improved and the fine aluminum hydroxide powder for filling in resin can be filled in resin per unit weight in a larger amount.

### (5) Na₂O Content

The content of Na₂O in aluminum hydroxide powder was determined in accordance with the method defined in JIS-R9301-3-9 after calcining an aluminum hydroxide powder under an air atmosphere at 1,100° C. for 2 hours.

### EXAMPLE 1

An aqueous sodium aluminate solution containing Na₂O in the concentration of 142 g/L and Al₂O₃ in the concentration of 143 g/L was mixed with an aqueous aluminum sulfate solution containing Al₂O₃ in the concentration of 8% by weight to obtain a neutralized gel in which a BET specific surface area is 38 m²/g and a peak intensity ratio I (001)/I (002) of a crystal plane (002) of gibbsite to a crystal plane (001) of bayerite is 0.7. This neutralized gel was added in an aqueous sodium aluminate solution containing Na₂O in the concentration of 142 g/L and supersaturated Al₂O₃ in the concentration of 64 g/L so that the amount of Al contained in the neutralized gel becomes 1.0% by weight based on the amount of Al in the solution, and then an ultrafine aluminum hydroxide was grown by stirring at a given temperature for 89 hours to obtain an aqueous sodium aluminate slurry containing seed aluminum hydroxide.

The obtained seed aluminum hydroxide exhibited a BET specific surface area of 3.6 m²/g, D50 of 1.8 μm, D10 of 0.82 μm, D90 of 3.2 μm (D90/D10 is 3.9), a Na₂O concentration of 0.10% by weight, and a peak intensity ratio I (110)/I (002) of 0.51.

This aqueous sodium aluminate slurry containing seed aluminum hydroxide exhibited the concentration of Al₂O₃ in the solution, which is lower than that of the saturated Al₂O₃ by 6.5 g/L, and had a solid content of 112 g/L.

In 10 parts by volume of this slurry, 28 parts by volume of an aqueous supersaturated sodium aluminate solution containing Na₂O in the concentration of 134 g/L and Al₂O₃ in the concentration of 136 g/L was continuously added to obtain an aqueous sodium aluminate slurry containing coarse aluminum hydroxide in which D50 is 5.7 μm, a peak intensity ratio I (110)/I (002) is 0.55, and the concentration of Na2O is 0.03% by weight. This slurry was subjected to solid-liquid separation by filtration and washed with hot water to form a wet coarse aluminum hydroxide having a moisture content of 25% by weight, which was then continuously fed in a single screw-type kneader (“MP-30-1”, manufactured by Miyazaki Tekko K.K.), ground, dried at 120° C. and pulverized to obtain a fine aluminum hydroxide powder for filling in resin.

The obtained fine aluminum hydroxide for filling in resin exhibited D50 of 2.4 μm, a maximum particle diameter D1 of 1.2 μm, D2 of 3.3 μm, D90/D10 of 4.7, a peak intensity ratio I (110)/I (002) of 0.36, an Na₂O concentration of 0.03% by weight, and DOP oil absorption of 40 ml/100 g. The results of the measurement of powder X-ray diffraction revealed that the obtained fine aluminum hydroxide for filling in resin is a gibbsite type aluminum hydroxide.

### EXAMPLE 2

A neutralized gel obtained in the same manner as in Example 1 was added in an aqueous sodium aluminate solution containing Na₂O in the concentration of 139 g/L and a supersaturated Al₂O₃ in the concentration of 65 g/L so that the amount of Al contained in the neutralized gel becomes 1% by weight based on the amount of Al in the solution, and then an ultrafine aluminum hydroxide was grown by stirring at a given temperature for 96 hours to obtain an aqueous sodium aluminate slurry containing seed aluminum hydroxide.

The obtained seed aluminum hydroxide exhibited a BET specific surface area of 3.7 m²/g, D50 of 1.7 μm, D10 of 0.76 μm, D90 of 3.1 μm (D90/D10 is 4.1), an Na₂O concentration of 0.09% by weight, and a peak intensity ratio I (110)/I (002) of 0.50. This aqueous sodium aluminate slurry containing seed aluminum hydroxide contained a supersaturated Al₂O₃ in the concentration of 7.9 g/L and had a solid content of 111 g/L.

In 10 parts by volume of this slurry, 27 parts by volume of an aqueous supersaturated sodium aluminate solution containing Na₂O in the concentration of 139 g/L and Al₂O₃ in the concentration of 142 g/L was continuously added to obtain an aqueous sodium aluminate slurry containing coarse aluminum hydroxide in which D50 is 5.3 μm, a peak intensity ratio I (110)/I (002) is 0.54, and an Na2O concentration is 0.03% by weight. This slurry was subjected to a solid-liquid separation by filtration and washed with hot water to form a wet coarse aluminum hydroxide having a moisture content of 25% by weight, which was then continuously fed in a single screw-type kneader (“MP-30-1”, manufactured by Miyazaki Tekko K.K.), ground, dried at 120° C. and pulverized to obtain a fine aluminum hydroxide powder for filling in resin.

The obtained fine aluminum hydroxide for filling in resin exhibited D50 of 2.8 μm, a maximum particle diameter D1 of 1.2 μm, D2 of 3.6 μm, D90/D10 of 5.1, a peak intensity ratio I (110)/I (002) of 0.39, an Na2O concentration of 0.03% by weight, and DOP oil absorption of 41 ml/100 g. The results of the measurement of powder X-ray diffraction revealed that the obtained fine aluminum hydroxide for filling in resin is a gibbsite type aluminum hydroxide.

### COMPARATIVE EXAMPLE 1

An aqueous sodium aluminate slurry containing coarse aluminum hydroxide in which D50 is 5.3 μm, a peak intensity ratio I (110)/I (002) is 0.54 and an Na₂O concentration is 0.03% by weight, synthesized in the same manner as in Example 2, was washed four times using a horizontal type decanter [Sharpless super decanter P-660, manufactured by TOMOE Engineering Co., Ltd.]. After washing, the aluminum hydroxide slurry was subjected to solid-liquid separation by filtration, dried at 120° C. and pulverized to obtain a fine aluminum hydroxide powder for filling in resin.

The obtained fine aluminum hydroxide for filling in resin exhibited D50 of 3.1 μm, a maximum particle diameter D1 of 1.2 μm, D2 of 3.9 μm, D90/D10 of 4.7, a peak intensity ratio I (110)/I (002) of 0.53, an Na₂O content of 0.03% by weight, and DOP oil absorption of 45 ml/100 g. The results of the measurement of powder X-ray diffraction revealed that the obtained fine aluminum hydroxide for filling in resin is a gibbsite type aluminum hydroxide.

### COMPARATIVE EXAMPLE 2

The neutralized gel obtained in Example 1 was added in an aqueous sodium aluminate solution containing Na₂O in the concentration of 144 g/L and a supersaturated Al₂O₃ in the concentration of 70 g/L so that the amount of Al contained in the neutralized gel becomes 1% by weight based on the amount of Al in the solution, and then an ultrafine aluminum hydroxide was grown by stirring at a given temperature for 90 hours to obtain an aqueous sodium aluminate slurry containing seed aluminum hydroxide.

The obtained seed aluminum hydroxide exhibited a BET specific surface area of 3.4 m²/g, D50 of 2.0 μm, D10 of 0.87 pm, D90 of 3.4 μm (D90/D10 is 3.9), an Na₂O concentration of 0.14% by weight, and a peak intensity ratio I (110)/I (002) of 0.50. This aqueous sodium aluminate slurry containing seed aluminum hydroxide contained a supersaturated Al₂O₃ in the concentration of 2.6 g/L and had a solid content of 117 g/L.

In 10 parts by volume of this slurry, 23 parts by volume of an aqueous supersaturated sodium aluminate solution containing Na₂O in the concentration of 143 g/L and Al₂O₃ in the concentration of 145 g/L was continuously added to obtain an aqueous sodium aluminate slurry containing coarse aluminum hydroxide in which D50 is 5.9 μm, an Na₂O concentration is 0.04% by weight, and a peak intensity ratio I (110)/I (002) is 0.54. This slurry was subjected to solid-liquid separation by filtration, washed with hot water and dried to obtain a coarse aluminum hydroxide powder. After placing 100 parts by weight of this coarse aluminum hydroxide powder and 3,900 parts by weight of alumina balls (15 mm φ) in a 3 L container, the coarse aluminum hydroxide powder was ground by a vibrating mill under the condition of an amplitude of 3 mm. After grinding and separation from alumina balls, a fine aluminum hydroxide powder for filling in resin was obtained.

This fine aluminum hydroxide powder for filling in resin exhibited D50 of 2.8 μm, a maximum particle diameter Dl of 1.3 μm, D2 of 3.6 μm, D90/D10 of 6.4, a peak intensity ratio I (110)/I (002) of 0.37, an Na₂O concentration of 0.04% by weight, and DOP oil absorption of 49 ml/100 g. The results of the measurement of powder X-ray diffraction revealed that the obtained fine aluminum hydroxide for filling in resin is a gibbsite type aluminum hydroxide.

### COMPARATIVE EXAMPLE 3

The seed aluminum hydroxide (3 parts by weight) in which D50 is 1.7 μm and an Na₂O concentration is 0.09% by weight, synthesized in Example 2, was mixed with 7 parts by weight of a coarse aluminum hydroxide in which D50 is 3.3 μm and an Na₂O concentration is 0.06% by weight collected in the course of continuously adding the aqueous supersaturated sodium aluminate solution in Example 2 to prepare a fine aluminum hydroxide powder for filling in resin.

This fine aluminum hydroxide powder for filling in resin exhibited D50 of 2.9 μm, a maximum particle diameter D1 of 1.3 μm, D2 of 3.6 μm, D90/D10 of 5.3, a peak intensity ratio I (110)/I (002) of 0.55, an Na₂O concentration of 0.07% by weight, and DOP oil absorption of 74 ml/100 g. The results of the measurement of powder X-ray diffraction revealed that the obtained fine aluminum hydroxide for filling in resin is a gibbsite type aluminum hydroxide.

### COMPARATIVE EXAMPLE 4

An aluminum hydroxide powder (30 parts by weight) in which D50 is 2.5 μm, an Na₂O concentration is 0.04% by weight, and a peak intensity ratio I (110)/I (002) is 0.54 was mixed with 70 parts by weight of pure water to prepare an aluminum hydroxide slurry, and the mixture was ground by an Apex mill (“AM-1”, manufactured by Kotobuki Industries Co., Ltd.). The grinding conditions are as follows.

Grinding media: 800 ml of 1 mm9 zirconia beads

Mill rotary speed: 1,900 rpm

Flow rate: 1 L/min

Number of grinding times: 3 times

After grinding, aluminum hydroxide exhibited a BET specific surface area of 8.8 m²/g, D50 of 1.5 μm, D10 of 0.76 pm, D90 of 2.9 μm (D90/D10 is 3.8), an Na2O concentration of 0.04% by weight, and a peak intensity ratio I (110)/I (002) of 0.28.

This aluminum hydroxide slurry was concentrated and 1.3 parts by weight (in terms of the solid content) of a slurry having a solid content of 50% by weight was added in 10 parts by volume of an aqueous sodium aluminate solution containing Na₂O in the concentration of 135 g/L and supersaturated Al₂O₃ in the concentration of 6 g/L to prepare an aqueous sodium aluminate slurry containing seed aluminum hydroxide. To this slurry, 8 parts by volume of an aqueous supersaturated sodium aluminate solution containing Na₂O in the concentration of 128 g/L and Al₂O₃ in the concentration of 128 g/L was gradually added, thereby precipitating a fine sodium hydroxide powder for filling in resin. This aqueous sodium aluminate slurry was filtered, washed and dried to obtain a fine sodium hydroxide powder for filling in resin.

This fine sodium hydroxide powder for filling in resin exhibited D50 of 1.0 μm, a maximum particle diameter Dl of 1.3 μm, D2 of 3.6 μm, D90/D10 of 4.8, a peak intensity ratio I (110)/I (002) of 0.22, and DOP oil absorption of 65 ml/100 g. The results of the measurement of powder X-ray diffraction revealed that the obtained fine aluminum hydroxide for filling in resin is a gibbsite type aluminum hydroxide.

### INDUSTRIAL APPLICABILITY

The fine aluminum hydroxide powder for filling in resin of the present invention is excellent in fillability in resin, and also contains considerably less coarse particles having a particle diameter of not less than 10 μm. Therefore, according to the present invention, it is possible to produce components having excellent flame retardancy and insulating stability even when miniaturized, such as electronic components which are excellent in safety.

1. A fine aluminum hydroxide powder for filling in resin, comprising a gibbsite crystal structure,
wherein a mean particle diameter is not less than 2.0 μm nor more than 4.0 μm in particle size distribution measured by a laser scattering diffraction method;
a ratio D90/D10 of a secondary particle diameter D10 corresponding to a point where a cumulative weight from a fine particle portion reaches 10%, to a secondary particle diameter D90 corresponding to a point where a cumulative weight from a fine particle portion reaches 90% is not less than 4.0 nor more than 6.0;
two or more frequency maximums exists in a particle diameter range I of not less than 0.5 μm nor more than 5.0 μm;
D2 and D1 satisfy the inequality expression (1):
2×D1≦D2≦4×D1 (1)
where D2 denotes a maximum particle diameter of a frequency maximum having a largest maximum particle diameter, among two or more frequency maximums existing in the particle diameter range I, and D1 denotes a maximum particle diameter of a frequency maximum having a smallest maximum particle diameter;
an intensity ratio I (110)/I (002) between peaks at crystal planes (110) and (002) measured by powder X-ray diffraction is not less than 0.30 nor more than 0.45; and
the total sodium content is not more than 0.10% by weight in terms of Na₂O.

2. The fine aluminum hydroxide powder for filling in resin according to claim 1, being subjected to a surface treatment with at least one selected from a group consisting of a silane coupling agent, a titanate coupling agent, an aliphatic carboxylic acid, an aromatic carboxylic acid, a fatty acid ester, and a silicate compound.

3. A method for producing fine aluminum hydroxide powder for filling in resin, comprising the steps (a) and (b):
step (a) of adding an aqueous supersaturated sodium aluminate solution to an aqueous sodium aluminate slurry containing seed aluminum hydroxide in which a BET specific surface area is not less than 2.0 m²/g nor more than 5.0 m²/g, a mean particle diameter measured by a laser scattering diffraction method in particle size distribution is not less than 1.0 μm and less than 3.0 μm, the total sodium content is not more than 0.20% by weight in terms of Na2O, and an intensity ratio I (110)/I (002) between peaks at crystal planes (110) and (002) is more than 0.45, thereby precipitating a coarse aluminum hydroxide in which an intensity ratio I (110)/I (002) between peaks at crystal planes (110) and (002) measured by powder X-ray diffraction is more than 0.45; and
step (b) of allowing a fine aluminum hydroxide powder for filling in resin obtained by grinding a coarse aluminum hydroxide being characterized in that a ratio D90/D10 of a secondary particle diameter D10 corresponding to a point where a cumulative weight from the fine particle portion reaches 10%, to a secondary particle diameter D90 which corresponding to a point where a cumulative weight from the fine particle portion reaches 90% is not less than 4.0 nor more than 6.0 in particle size distribution measured by a laser scattering diffraction method, and an intensity ratio I (110)/I (002) between peaks at crystal planes (110) and (002) measured by powder X-ray diffraction is not less than 0.30 nor more than 0.45.

4. The method according to claim 3, wherein a ratio of D90/D10 of a secondary particle diameter D10 corresponding to the point where the cumulative weight from the fine particle portion reaches 10%, to a secondary particle diameter D90 corresponding to the point where the cumulative weight from the fine particle portion reaches 90% of the seed aluminum hydroxide is not less than 2.0 nor more than 5.0 in particle size distribution measured by a laser scattering diffraction method.

5. A resin composition comprising:
a resin; and
the fine aluminum hydroxide powder for filling in resin according to claim 1.

6. A prepreg comprising the resin composition according to claim 5.

7. A printed circuit board comprising the resin composition according to claim 5.

8. A resin composition comprising:
a resin; and
the fine aluminum hydroxide powder for filling in resin according to claim 2.

9. A prepreg comprising the resin composition according to claim 8.

10. A printed circuit board comprising the resin composition according to claim 8.
